(19) United States
(12) Patent Application Publication
(10) Pub. No.: US 2020/0077535 A1
(43) Pub. Date: Mar. 5, 2020

(54) REMOVABLE I/O EXPANSION DEVICE FOR DATA CENTER STORAGE RACK

(71) Applicant: Fungible, Inc., Santa Clara, CA (US)

(72) Inventors: Sunil Mekad, Bangalore (IN); Ravichandran Venkatachalam, Bangalore (IN); Prathap Sirishe, Milpitas, CA (US); Satish D. Deo, Cupertino, CA (US)

(21) Appl. No.: 16/546,185

(22) Filed: Aug. 20, 2019

(30) Foreign Application Priority Data
Sep. 5, 2018 (IN) 201841033315

(51) Int. Cl. H05K 7/14; G06F 13/40; G06F 13/12

(52) U.S. Cl. CPC H05K 7/1492; H05K 7/1489; G06F 2213/0026; G06F 13/4022; G06F 13/122; H05K 7/1438

(57) ABSTRACT

Techniques are disclosed for an Input/Output (I/O) expansion device configured for slidable insertion within and removal from a plurality of slots of a storage rack having an electrical backplane comprising a plurality of high-speed Peripheral Component Interconnect Express (PCIe) lanes. The I/O expansion device operates as a multi-slot front caddy that extends an I/O interface of the storage rack to allow interconnection with storage and/or compute equipment external from the rack. The I/O expansion device comprises a front plate comprising an aggregate electrical storage connector configured to interface with storage and computing devices. The I/O expansion device comprises a rear plate comprising backplane electrical connectors configured to interface with the high-speed PCIe lanes of the electrical backplane. The I/O expansion device presents, via the backplane electrical connectors, an aggregate bandwidth of the high-speed PCIe lanes to the storage and computing devices interfaced with the aggregate electrical storage connector.

This application claims the benefit of India Provisional Application No. 201841033315 filed on Sep. 5, 2018, the entire content of which is incorporated herein by reference.

### TECHNICAL FIELD

This disclosure generally relates to computer networks and, more particularly, expansion devices for shelves within network racks and cabinets of data center.

### BACKGROUND

In a typical cloud-based data center, a large collection of interconnected servers provides computing and/or storage capacity for execution of various applications. For example, a data center may comprise a facility that hosts applications and services for subscribers, i.e., customers of the data center. The data center may, for example, host all of the infrastructure equipment, such as compute nodes, networking and storage systems, power systems and environmental control systems.

In most data centers, clusters of storage systems and application servers are interconnected via a high-speed switch fabric provided by one or more tiers of physical network switches and routers. Data centers vary greatly in size, with some public data centers containing hundreds of thousands of servers, and are usually distributed across multiple geographies for redundancy. A typical data center switch fabric includes multiple tiers of interconnected switches and routers. In current implementations, packets for a given packet flow between a source server and a destination server or storage system are always forwarded from the source to the destination along a single path through the routers and switches comprising the switching fabric.

### SUMMARY

In general, the disclosure describes an input/output (I/O) expansion device configured for slidable insertion within and removal from a plurality of slots (e.g., two) of a storage rack. The I/O expansion device operates as a multi-slot front caddy that is designed to extend an I/O interface of the storage rack so as to allow interconnection with storage and/or compute equipment external from the rack. Moreover, as described herein, using the multi-slot I/O expansion device, the external storage and/or compute nodes can be conveniently connected to an I/O interface via the front of the storage rack. In one example, the multi-slot caddy extends the I/O interface of a storage rack without requiring extra physical space or power but instead occupies the same space and utilizes the power otherwise allocated for front-loaded solid-state or hard disk drives typically inserted within the slots of the storage rack.

In one example, this disclosure describes a removable Input/Output (I/O) expansion device. The I/O expansion device is configured for slidable insertion within and removal from a plurality of slots of a storage rack that has an electrical backplane comprising a plurality of high-speed Peripheral Component Interconnect Express (PCIe) lanes. In some examples, the I/O expansion device comprises a front plate comprising an aggregate electrical storage connector mounted thereon. The aggregate electrical storage connector is configured to interface with one or more storage devices and computing devices. The I/O expansion device further includes a rear plate comprising a plurality of backplane electrical connectors mounted thereon. The plurality of backplane electrical connectors are configured to interface with the plurality of high-speed PCIe lanes of the electrical backplane of the storage rack. The I/O expansion device further includes interface circuitry mounted on a printed circuit board within the I/O expansion device and electrically coupled to the backplane electrical connectors of the rear plate and the aggregate electrical storage connector of the front plate. The interface circuitry of the I/O expansion device is configured to present, via the plurality of backplane electrical connectors, an aggregate bandwidth of the plurality of high-speed PCIe lanes to the one or more storage devices and computing devices interfaced with the aggregate electrical storage connector.

In another example, this disclosure describes a method of forming a removable I/O expansion device configured for slidable insertion within and removal from a plurality of slots of a storage rack having an electrical backplane. The electrical backplane comprises a plurality of high-speed Peripheral Component Interconnect Express (PCIe) lane. In some examples, the method includes forming a front plate comprising an aggregate electrical storage connector mounted thereon. The method further includes forming a rear plate comprising a plurality of backplane electrical connectors mounted thereon. Further, the method includes forming interface circuitry mounted on a printed circuit board within the I/O expansion device and electrically coupled to the backplane electrical connectors of the rear plate and the aggregate electrical storage connector of the front plate.

The details of one or more examples of the techniques of this disclosure are set forth in the accompanying drawings and the description below. Other features, objects, and advantages of the techniques will be apparent from the description and drawings, and from the claims.

### BRIEF DESCRIPTION OF DRAWINGS

FIG. 1 is a block diagram illustrating an example network having a data center in which examples of the techniques described herein may be implemented.

FIG. 2 is a block diagram illustrating an example data processing unit (DPU) of FIG. 1 in further detail.

FIG. 3 is a block diagram illustrating one example of network storage compute unit (NSCU) 40 including a DPU and its supported storage and compute nodes.

FIG. 4 is a block diagram illustrating an example arrangement of a full physical rack in which examples of the techniques described herein may be implemented.

FIG. 5 is an illustration depicting an example server rack that includes a plurality of storage devices and I/O expansion devices in accordance with the techniques of the disclosure.

FIG. 6 is an illustration depicting another perspective of the example server rack of FIG. 5.

FIGS. 7A-7B are illustrations depicting an isometric view of an example expansion device in accordance with the techniques of the disclosure.

FIGS. 8A-8B are illustrations depicting additional perspectives of the example expansion device of FIGS. 7A-7B.

FIG. 9 is an illustration depicting an exploded view of the example expansion device of FIGS. 7A-7B.

Like reference characters refer to like elements throughout the figures and description.

### DETAILED DESCRIPTION

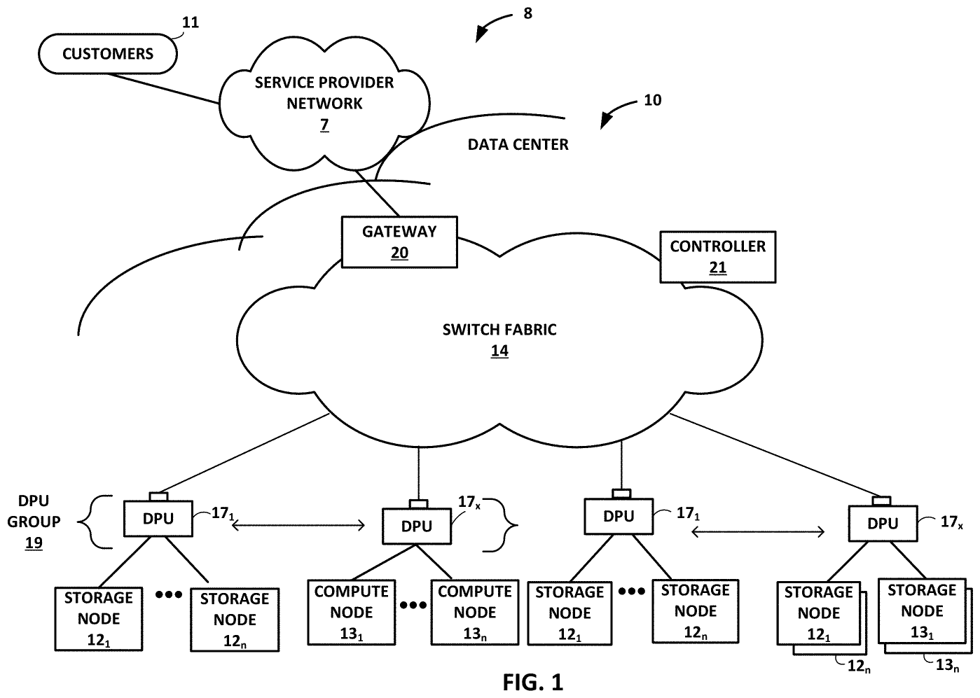

FIG. 1 is a block diagram illustrating an example system 8 having a data center 10 in which examples of the techniques described herein may be implemented. In general, data center 10 provides an operating environment for applications and services for customers 11 coupled to the data center by content/service provider network 7 and gateway device 20. In other examples, content/service provider network 7 may be a data center wide-area network (DC WAN), private network or other type of network. Data center 10 may, for example, host infrastructure equipment, such as compute nodes, networking and storage systems, redundant power supplies, and environmental controls. Content/service provider network 7 may be coupled to one or more networks administered by other providers, and may thus form part of a large-scale public network infrastructure, e.g., the Internet.

In some examples, data center 10 may represent one of many geographically distributed network data centers. In the example of FIG. 1, data center 10 is a facility that provides information services for customers 11. Customers 11 may be collective entities such as enterprises and governments or individuals. For example, a network data center may host web services for several enterprises and end users. Other exemplary services may include data storage, virtual private networks, file storage services, data mining services, scientific- or super-computing services, and so on.

In this example, data center 10 includes a set of storage nodes 12 and compute nodes 13 interconnected via a high-speed switch fabric 14. In some examples, storage nodes 12 and compute nodes 13 are arranged into multiple different groups, each including any number of nodes up to, for example, n storage nodes 12₁-12ₙ and n compute nodes 13₁-13ₙ (collectively, “storage nodes 12” and “compute nodes 13”). Storage nodes 12 and compute nodes 13 provide storage and computation facilities, respectively, for applications and data associated with customers 11 and may be physical (bare-metal) servers, virtual machines running on physical servers, virtualized containers running on physical servers, or combinations thereof.

In the example of FIG. 1, software-defined networking (SDN) controller 21 provides a high-level controller for configuring and managing the routing and switching infrastructure of data center 10. SDN controller 21 provides a logically and in some cases physically centralized controller for facilitating operation of one or more virtual networks within data center 10 in accordance with one or more embodiments of this disclosure. In some examples, SDN controller 21 may operate in response to configuration input received from a network administrator. In some examples, SDN controller 21 operates to configure data processing units (DPUs) 17 to logically establish one or more virtual fabrics as overlay networks dynamically configured on top of the physical underlay network provided by switch fabric 14. For example, SDN controller 21 may learn and maintain knowledge of DPUs 17 and establish a communication control channel with each of DPUs 17. SDN controller 21 uses its knowledge of DPUs 17 to define multiple sets (groups) of two of more DPUs 17 to establish different virtual fabrics over switch fabric 14. More specifically, SDN controller 21 may use the communication control channels to notify each of DPUs 17 for a given set which other DPUs 17 are included in the same set. In response, DPUs 17 dynamically setup FCP tunnels with the other DPUs included in the same set as a virtual fabric over packet switched network 410. In this way, SDN controller 21 defines the sets of DPUs 17 for each of the virtual fabrics, and the DPUs are responsible for establishing the virtual fabrics. As such, underlay components of switch fabric 14 may be unware of virtual fabrics. In these examples, DPUs 17 interface with and utilize switch fabric 14 so as to provide full mesh (any-to-any) interconnectivity between DPUs of any given virtual fabric. In this way, the servers connected to any of the DPUs forming a given one of virtual fabrics may communicate packet data for a given packet flow to any other of the servers coupled to the DPUs for that virtual fabric using any of a number of parallel data paths within switch fabric 14 that interconnect the DPUs of that virtual fabric. More details of DPUs operating to spray packets within and across virtual overlay networks are available in U.S. Provisional Patent Application No. 62/638,788, filed Mar. 5, 2018, entitled “NETWORK DPU VIRTUAL FABRICS CONFIGURED DYNAMICALLY OVER AN UNDERLAY NETWORK” (Attorney Docket No. 1242-036USP1) and U.S. patent application Ser. No. 15/939,227, filed Mar. 28, 2018, entitled “NON-BLOCKING ANY-TO-ANY DATA CENTER NETWORK WITH PACKET SPRAYING OVER MULTIPLE ALTERNATE DATA PATHS” (Attorney Docket No. 1242-002US01), the entire contents of each of which are incorporated herein by reference.

Although not shown, data center 10 may also include, for example, one or more non-edge switches, routers, hubs, gateways, security devices such as firewalls, intrusion detection, and/or intrusion prevention devices, servers, computer terminals, laptops, printers, databases, wireless mobile devices such as cellular phones or personal digital assistants, wireless access points, bridges, cable modems, application accelerators, or other network devices.

In the example of FIG. 1, each of storage nodes 12 and compute nodes 13 is coupled to switch fabric 14 by a DPU 17. As further described herein, in one example, each DPU 17 is a highly programmable I/O processor specially designed for offloading certain functions from storage nodes 12 and compute nodes 13. In one example, each of DPUs 17 includes one or more processing cores consisting of a number of internal processor clusters, e.g., MIPS cores, equipped with hardware engines that offload cryptographic functions, compression and regular expression (RegEx) processing, data storage functions and networking operations. In this way, each DPU 17 includes components for fully implementing and processing network and storage stacks on behalf of one or more storage nodes 12 or compute nodes 13. In addition, DPUs 17 may be programmatically configured to serve as a security gateway for its respective storage nodes 12 or compute nodes 13, freeing up the processors of the servers to dedicate resources to application workloads. In some example implementations, each DPU 17 may be viewed as a network interface subsystem that implements full offload of the handling of data packets (with zero copy in server memory) and storage acceleration for the attached server systems. In one example, each DPU 17 may be implemented as one or more application-specific integrated circuit (ASIC) or other hardware and software components, each supporting a subset of the servers. DPUs 17 may also be referred to as access nodes, or devices including access nodes. In other words, the term access node may be used herein interchangeably with the term DPU. Additional example details of various example DPUs are described in U.S. Provisional Patent Application No. 62/559,021, filed Sep. 15, 2017, entitled “Access Node for Data Centers,” and U.S. Provisional Patent Application No. 62/530,691, filed Jul. 10, 2017, entitled “Data Processing Unit for Computing Devices,” the entire contents of both being incorporated herein by reference

In example implementations, DPUs 17 are configurable to operate in a standalone network appliance having one or more DPUs. For example, DPUs 17 may be arranged into multiple different DPU groups 19, each including any number of DPUs up to, for example, x DPUs 17₁-17ₓ. As such, multiple DPUs 17 may be grouped (e.g., within a single electronic device or network appliance), referred to herein as a DPU group 19, for providing services to a group of servers supported by the set of DPUs internal to the device. In one example, a DPU group 19 may comprise four DPUs 17, each supporting four servers so as to support a group of sixteen servers.

In the example of FIG. 1, each DPU 17 provides connectivity to switch fabric 14 for a different group of storage nodes 12 or compute nodes 13 and may be assigned respective IP addresses and provide routing operations for the storage nodes 12 or compute nodes 13 coupled thereto. As described herein, DPUs 17 provide routing and/or switching functions for communications from/directed to the individual storage nodes 12 or compute nodes 13. For example, as shown in FIG. 1, each DPU 17 includes a set of edge-facing electrical or optical local bus interfaces for communicating with a respective group of storage nodes 12 or compute nodes 13 and one or more core-facing electrical or optical interfaces for communicating with core switches within switch fabric 14. In addition, DPUs 17 described herein may provide additional services, such as storage (e.g., integration of solid-state storage devices), security (e.g., encryption), acceleration (e.g., compression), I/O offloading, and the like. In some examples, one or more of DPUs 17 may include storage devices, such as high-speed solid-state drives or rotating hard drives, configured to provide network accessible storage for use by applications executing on the servers. Although not shown in FIG. 1, DPUs 17 may be directly coupled to each other, such as direct coupling between DPUs in a common DPU group 19, to provide direct interconnectivity between the DPUs of the same group. For example, multiple DPUs 17 (e.g., 4 DPUs) may be positioned within a common DPU group 19 for servicing a group of servers (e.g., 16 servers).

As one example, each DPU group 19 of multiple DPUs 17 may be configured as standalone network device, and may be implemented as a two rack unit (2RU) device that occupies two rack units (e.g., slots) of an equipment rack. In another example, DPU 17 may be integrated within a server, such as a single 1RU server in which four CPUs are coupled to the forwarding ASICs described herein on a mother board deployed within a common computing device. In yet another example, one or more of DPUs 17, storage nodes 12, and compute nodes 13 may be integrated in a suitable size (e.g., 10RU) frame that may, in such an example, become a network storage compute unit (NSCU) for data center 10. For example, a DPU 17 may be integrated within a mother board of a storage node 12 or a compute node 13 or otherwise co-located with a server in a single chassis.

In some example implementations, DPUs 17 interface and utilize switch fabric 14 so as to provide full mesh (any-to-any) interconnectivity such that any of storage nodes 12 or compute nodes 13 may communicate packet data for a given packet flow to any other of the servers using any of a number of parallel data paths within the data center 10. For example, in some example network architectures, DPUs spray individual packets for packet flows between the DPUs and across some or all of the multiple parallel data paths in the data center switch fabric 14 and reorder the packets for delivery to the destinations so as to provide full mesh connectivity.

In this way, DPUs 17 interface and utilize switch fabric 14 so as to provide full mesh (any-to-any) interconnectivity such that any of storage nodes 12 or compute nodes 13 may communicate packet data for a given packet flow to any other of the servers using any of a number of parallel data paths within the data center 10. For example, in some example network architectures, DPUs spray individual packets for packet flows between the DPUs and across some or all of the multiple parallel data paths in the data center switch fabric 14 and reorder the packets for delivery to the destinations so as to provide full mesh connectivity.

As described herein, a data transmission protocol referred to as a Fabric Control Protocol (FCP) may be used by the different operational networking components of any of DPUs 17 to facilitate communication of data across switch fabric 14. As further described, FCP is an end-to-end admission control protocol in which, in one example, a sender explicitly requests a receiver with the intention to transfer a certain number of bytes of payload data. In response, the receiver issues a grant based on its buffer resources, QoS, and/or a measure of fabric congestion. In general, FCP enables spray of packets of a flow to all paths between a source and a destination node, and may provide numerous advantages, including resilience against request/grant packet loss, adaptive and low latency fabric implementations, fault recovery, reduced or minimal protocol overhead cost, support for unsolicited packet transfer, support for FCP capable/incapable nodes to coexist, flow-aware fair bandwidth distribution, transmit buffer management through adaptive request window scaling, receive buffer occupancy based grant management, improved end to end QoS, security through encryption and end to end authentication and/or improved ECN marking support. More details on the FCP are available in U.S. Provisional Patent Application No. 62/566,060, filed Sep. 29, 2017, entitled “Fabric Control Protocol for Data Center Networks with Packet Spraying Over Multiple Alternate Data Paths,” the entire content of which is incorporated herein by reference.

The use of FCP may provide certain advantages. For example, the use of FCP may increase significantly the bandwidth utilization of the underlying switch fabric 14. Moreover, in example implementations described herein, the servers of the data center may have full mesh interconnectivity and may nevertheless be non-blocking and drop-free.

Although DPUs 17 are described in FIG. 1 with respect to switch fabric 14 of data center 10, in other examples, DPUs may provide full mesh interconnectivity over any packet switched network. For example, the packet switched network may include a local area network (LAN), a wide area network (WAN), or a collection of one or more networks. The packet switched network may have any topology, e.g., flat or multi-tiered, as long as there is full connectivity between the DPUs. The packet switched network may use any technology, including IP over Ethernet as well as other technologies. Irrespective of the type of packet switched network, DPUs may spray individual packets for packet flows between the DPUs and across multiple parallel data paths in the packet switched network and reorder the packets for delivery to the destinations so as to provide full mesh connectivity.

In accordance with the techniques of the disclosure, an I/O expansion device is disclosed that is configured for slidable insertion within and removal from a plurality of slots (e.g., two) of a storage rack of data center 10. As described in further detail below, the I/O expansion device operates as a multi-slot front caddy that is designed to extend an I/O interface of the storage rack so as to allow interconnection between DPUs 17 and storage nodes 12 and/or compute nodes 13 external from the rack. Moreover, as described herein, using the multi-slot I/O expansion device, the external storage nodes 12 and/or compute nodes 13 can be conveniently connected to an I/O interface via the front of the storage rack. In one example, the multi-slot caddy extends the I/O interface of a storage rack without requiring extra physical space or power but instead occupies the same space and utilizes the power otherwise allocated for front-loaded solid-state or hard disk drives typically inserted within the slots of the storage rack.

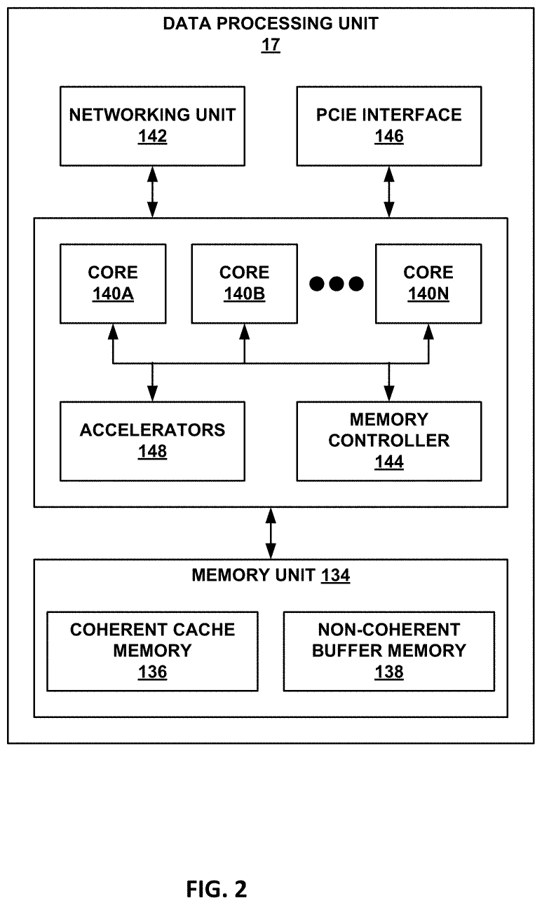

FIG. 2 is a block diagram illustrating an example DPU 17 of FIG. 1 in further detail. DPU 17 generally represents a hardware chip implemented in digital logic circuitry. DPU 17 may operate substantially similar to any of DPUs 17₁-17_{N} of FIG. 1. Thus, DPU 17 may be communicatively coupled to a CPU, a GPU, one or more network devices, server devices, random access memory, storage media (e.g., solid state drives (SSDs)), a data center fabric, or the like, e.g., via PCI-e, Ethernet (wired or wireless), or other such communication media.

In the illustrated example of FIG. 2, DPU 17 includes a plurality of programmable processing cores 140A-140N (“cores 140”) and a memory unit 134. Memory unit 134 may include two types of memory or memory devices, namely coherent cache memory 136 and non-coherent buffer memory 138. In some examples, plurality of cores 140 may include at least two processing cores. In one specific example, plurality of cores 140 may include six processing cores. DPU 17 also includes a networking unit 142, one or more PCIe interfaces 146, a memory controller 144, and one or more accelerators 148. As illustrated in FIG. 2, each of cores 140, networking unit 142, memory controller 144, PCIe interfaces 146, accelerators 148, and memory unit 134 including coherent cache memory 136 and non-coherent buffer memory 138 are communicatively coupled to each other.

In this example, DPU 17 represents a high performance, hyper-converged network, storage, and data processor and input/output hub. Cores 140 may comprise one or more of MIPS (microprocessor without interlocked pipeline stages) cores, ARM (advanced RISC (reduced instruction set computing) machine) cores, PowerPC (performance optimization with enhanced RISC—performance computing) cores, RISC-V (RISC five) cores, or CISC (complex instruction set computing or x86) cores. Each of cores 140 may be programmed to process one or more events or activities related to a given data packet such as, for example, a networking packet or a storage packet. Each of cores 140 may be programmable using a high-level programming language, e.g., C, C++, or the like.

As described herein, the new processing architecture utilizing a DPU may be especially efficient for stream processing applications and environments. For example, stream processing is a type of data processing architecture well suited for high performance and high efficiency processing. A stream is defined as an ordered, unidirectional sequence of computational objects that can be of unbounded or undetermined length. In a simple embodiment, a stream originates in a producer and terminates at a consumer, and is operated on sequentially. In some embodiments, a stream can be defined as a sequence of stream fragments; each stream fragment including a memory block contiguously addressable in physical address space, an offset into that block, and a valid length. Streams can be discrete, such as a sequence of packets received from the network, or continuous, such as a stream of bytes read from a storage device. A stream of one type may be transformed into another type as a result of processing. For example, TCP receive (Rx) processing consumes segments (fragments) to produce an ordered byte stream. The reverse processing is performed in the transmit (Tx) direction. Independently of the stream type, stream manipulation requires efficient fragment manipulation, where a fragment is as defined above.

In some examples, the plurality of cores 140 may be capable of processing a plurality of events related to each data packet of one or more data packets, received by networking unit 142 and/or PCIe interfaces 146, in a sequential manner using one or more “work units.” In general, work units are sets of data exchanged between cores 140 and networking unit 142 and/or PCIe interfaces 146 where each work unit may represent one or more of the events related to a given data packet of a stream. As one example, a Work Unit (WU) is a container that is associated with a stream state and used to describe (i.e. point to) data within a stream (stored). For example, work units may dynamically originate within a peripheral unit coupled to the multi-processor system (e.g. injected by a networking unit, a host unit, or a solid state drive interface), or within a processor itself, in association with one or more streams of data, and terminate at another peripheral unit or another processor of the system. The work unit is associated with an amount of work that is relevant to the entity executing the work unit for processing a respective portion of a stream. In some examples, one or more processing cores of a DPU may be configured to execute program instructions using a work unit (WU) stack.

In some examples, in processing the plurality of events related to each data packet, a first one of the plurality of cores 140, e.g., core 140A may process a first event of the plurality of events. Moreover, first core 140A may provide to a second one of plurality of cores 140, e.g., core 140B a first work unit of the one or more work units. Furthermore, second core 140B may process a second event of the plurality of events in response to receiving the first work unit from first core 140B.

DPU 17 may act as a combination of a switch/router and a number of network interface cards. For example, networking unit 142 may be configured to receive one or more data packets from and transmit one or more data packets to one or more external devices, e.g., network devices. Networking unit 142 may perform network interface card functionality, packet switching, and the like, and may use large forwarding tables and offer programmability. Networking unit 142 may expose Ethernet ports for connectivity to a network, such as network 7 of FIG. 1. In this way, DPU 17 supports one or more high-speed network interfaces, e.g., Ethernet ports, without the need for a separate network interface card (NIC). Each of PCIe interfaces 146 may support one or more PCIe interfaces, e.g., PCIe ports, for connectivity to an application processor (e.g., an x86 processor of a server device or a local CPU or GPU of the device hosting DPU 17) or a storage device (e.g., an SSD). DPU 17 may also include one or more high bandwidth interfaces for connectivity to off-chip external memory (not illustrated in FIG. 2). Each of accelerators 148 may be configured to perform acceleration for various data-processing functions, such as look-ups, matrix multiplication, cryptography, compression, regular expressions, or the like. For example, accelerators 148 may comprise hardware implementations of look-up engines, matrix multipliers, cryptographic engines, compression engines, regular expression interpreters, or the like.

Memory controller 144 may control access to memory unit 134 by cores 140, networking unit 142, and any number of external devices, e.g., network devices, servers, external storage devices, or the like. Memory controller 144 may be configured to perform a number of operations to perform memory management in accordance with the present disclosure. For example, memory controller 144 may be capable of mapping accesses from one of the cores 140 to either of coherent cache memory 136 or non-coherent buffer memory 138. In some examples, memory controller 144 may map the accesses based on one or more of an address range, an instruction or an operation code within the instruction, a special access, or a combination thereof.

Additional details regarding the operation and advantages of the DPU are available in U.S. patent application Ser. No. 16/031,921, filed Jul. 10, 2018, and titled “DATA PROCESSING UNIT FOR COMPUTE NODES AND STORAGE NODES,” (Attorney Docket No. 1242-004US01) and U.S. patent application Ser. No. 16/031,676, filed Jul. 10, 2018, and titled “ACCESS NODE FOR DATA CENTERS” (Attorney Docket No. 1242-005US01), the entire content of each of which is incorporated herein by reference.

In accordance with the techniques of the disclosure, an I/O expansion device is disclosed that is configured for slidable insertion within and removal from a plurality of slots (e.g., two) of a storage rack of data center 10. As described in further detail below, the I/O expansion device operates as a multi-slot front caddy that is designed to extend an I/O interface of the storage rack so as to allow interconnection between DPUs 17 and storage nodes 12 and/or compute nodes 13 external from the rack. With respect to the example of FIG. 2, the I/O expansion device serves to extend PCIe interface 146 of DPU 17 interfaced with an I/O interface of the storage rack to external storage nodes 12 and/or compute nodes 13. Moreover, as described herein, using the multi-slot I/O expansion device, the external storage nodes 12 and/or compute nodes 13 can be conveniently connected to PCIe interface 146 of DPU 17 via the front of the storage rack. In one example, the multi-slot caddy extends PCIe interface 146 of DPU without requiring extra physical space or power but instead occupies the same space and utilizes the power otherwise allocated for front-loaded solid-state or hard disk drives typically inserted within the slots of the storage rack.

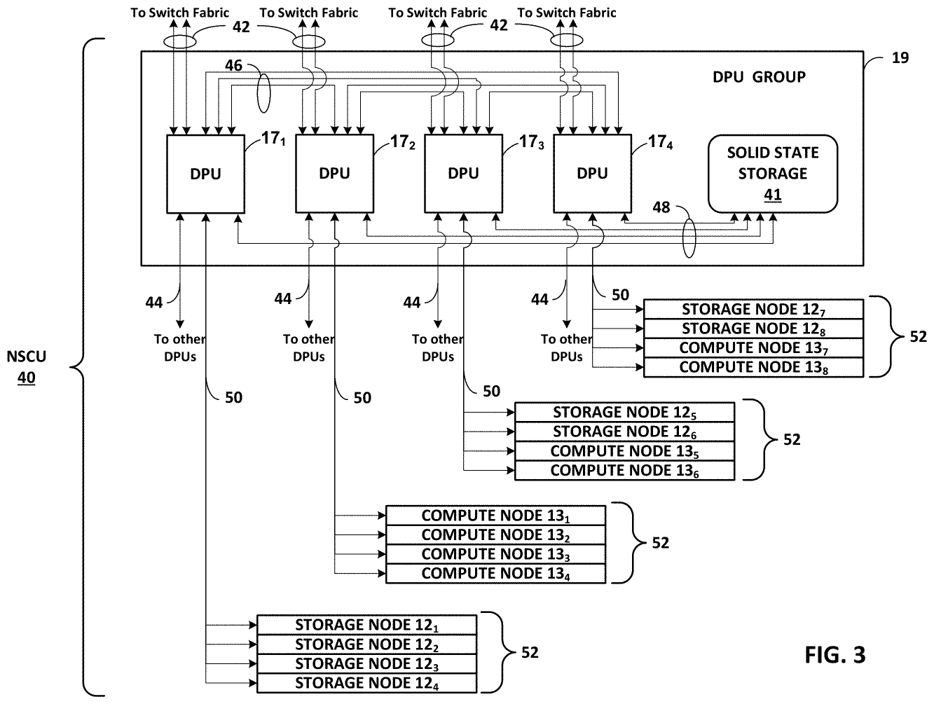

FIG. 3 is a block diagram illustrating one example of network storage compute unit (NSCU) 40 including a DPU group 19 and its supported node group 52. DPU group 19 may be configured to operate as a high-performance I/O hub designed to aggregate and process network and storage I/O to multiple node groups 52. In the particular example of FIG. 3, DPU group 19 includes four DPUs 17₁-17₄ (collectively, “DPUs 17”) connected to a pool of local solid state storage 41. In the illustrated example, DPU group 19 supports a total of eight storage nodes 12₁-12₈ (collectively, “storage nodes 12”) and eight compute nodes 13₁-13₈ (collectively, compute nodes 13) with each of the four DPUs 17 within DPU group 19 supporting four of storage nodes 12 and compute nodes 13. In some examples, each of the four storage nodes 12 and/or compute nodes 13 supported by each of the DPUs 17 may be arranged as a node group 52. In some examples, the “storage nodes 12” or “compute nodes 13” described throughout this application may be dual-socket or dual-processor “storage nodes” or “compute nodes” that are arranged in groups of two or more within a standalone device, e.g., node group 52. In the example of FIG. 3, a DPU supports four nodes of storage nodes 12 and/or compute nodes 13. The 4 nodes may be any combination of storage nodes 12 and/or compute nodes 13 (e.g., 4 storage nodes 12 and 0 compute nodes 13, 2 storage nodes 12 and 2 compute nodes 13, 1 storage node 12 and 3 compute nodes 13, 0 storage nodes 12 and 4 compute nodes 13, etc.).

Although DPU group 19 is illustrated in FIG. 3 as including four DPUs 17 that are all connected to a single pool of solid state storage 41, a DPU group may be arranged in other ways. In one example, each of the four DPUs 17 may be included on an individual DPU sled that also includes solid state storage and/or other types of storage for the DPU. In this example, a DPU group may include four DPU sleds each having a DPU and a set of local storage devices.

In one example implementation, DPUs 17 within DPU group 19 connect to node groups 52 and solid state storage 41 using Peripheral Component Interconnect express (PCIe) links 48, 50, and connect to other DPUs and the datacenter switch fabric 14 using Ethernet links 42, 44, 46. For example, each of DPUs 17 may support six high-speed Ethernet connections, including two externally-available Ethernet connections 42 for communicating with the switch fabric, one externally-available Ethernet connection 44 for communicating with other DPUs in other DPU groups, and three internal Ethernet connections 46 for communicating with other DPUs 17 in the same DPU group 19. In one example, each of externally-available connections 42 may be a 100 Gigabit Ethernet (GE) connection. In this example, DPU group 19 has 8×100 GE externally-available ports to connect to the switch fabric 14.

Within DPU group 19, connections 42 may be copper, i.e., electrical, links arranged as 8×25 GE links between each of DPUs 17 and optical ports of DPU group 19. Between DPU group 19 and the switch fabric, connections 42 may be optical Ethernet connections coupled to the optical ports of DPU group 19. The optical Ethernet connections may connect to one or more optical devices within the switch fabric, e.g., optical permutation devices described in more detail below. The optical Ethernet connections may support more bandwidth than electrical connections without increasing the number of cables in the switch fabric. For example, each optical cable coupled to DPU group 19 may carry 4×100 GE optical fibers with each fiber carrying optical signals at four different wavelengths or lambdas. In other examples, the externally-available connections 42 may remain as electrical Ethernet connections to the switch fabric.

The four remaining Ethernet connections supported by each of DPUs 17 include one Ethernet connection 44 for communication with other DPUs within other DPU groups, and three Ethernet connections 46 for communication with the other three DPUs within the same DPU group 19. In some examples, connections 44 may be referred to as “inter-DPU group links” and connections 46 may be referred to as “intra-DPU group links.”

Ethernet connections 44, 46 provide full-mesh connectivity between DPUs within a given structural unit. In one example, such a structural unit may be referred to herein as a logical rack (e.g., a half-rack or a half physical rack) that includes two NSCUs 40 having two AGNs 19 and supports an 8-way mesh of eight DPUs 17 for those AGNs. In this particular example, connections 46 would provide full-mesh connectivity between the four DPUs 17 within the same DPU group 19, and connections 44 would provide full-mesh connectivity between each of DPUs 17 and four other DPUs within one other DPU group of the logical rack (i.e., structural unit). In addition, DPU group 19 may have enough, e.g., sixteen, externally-available Ethernet ports to connect to the four DPUs in the other DPU group.

In the case of an 8-way mesh of DPUs, i.e., a logical rack of two NSCUs 40, each of DPUs 17 may be connected to each of the other seven DPUs by a 50 GE connection. For example, each of connections 46 between the four DPUs 17 within the same DPU group 19 may be a 50 GE connection arranged as 2×25 GE links. Each of connections 44 between the four DPUs 17 and the four DPUs in the other DPU group may include four 50 GE links. In some examples, each of the four 50 GE links may be arranged as 2×25 GE links such that each of connections 44 includes 8×25 GE links to the other DPUs in the other DPU group.

In another example, Ethernet connections 44, 46 provide full-mesh connectivity between DPUs within a given structural unit that is a full-rack or a full physical rack that includes four NSCUs 40 having four AGNs 19 and supports a 16-way mesh of DPUs 17 for those AGNs. In this example, connections 46 provide full-mesh connectivity between the four DPUs 17 within the same DPU group 19, and connections 44 provide full-mesh connectivity between each of DPUs 17 and twelve other DPUs within three other DPU group. In addition, DPU group 19 may have enough, e.g., forty-eight, externally-available Ethernet ports to connect to the four DPUs in the other DPU group.

In the case of a 16-way mesh of DPUs, each of DPUs 17 may be connected to each of the other fifteen DPUs by a 25 GE connection, for example. In other words, in this example, each of connections 46 between the four DPUs 17 within the same DPU group 19 may be a single 25 GE link. Each of connections 44 between the four DPUs 17 and the twelve other DPUs in the three other DPU groups may include 12×25 GE links.

As shown in FIG. 3, each of DPUs 17 within a DPU group 19 may also support a set of high-speed PCIe connections 48, 50, e.g., PCIe Gen 3.0 or PCIe Gen 4.0 connections, for communication with solid state storage 41 within DPU group 19 and communication with node groups 52 within NSCU 40. Each of node groups 52 includes four storage nodes 12 and/or compute nodes 13 supported by one of DPUs 17 within DPU group 19. Solid state storage 41 may be a pool of Non-Volatile Memory express (NVMe)-based solid state drive (SSD) storage devices accessible by each of DPUs 17 via connections 48.

In one example, solid state storage 41 may include twenty-four SSD devices with six SSD devices for each of DPUs 17. The twenty-four SSD devices may be arranged in four rows of six SSD devices with each row of SSD devices being connected to one of DPUs 17. Each of the SSD devices may provide up to 16 Terabytes (TB) of storage for a total of 384 TB per DPU group 19. As described in more detail below, in some cases, a physical rack may include four DPU groups 19 and their supported node groups 52. In that case, a typical physical rack may support approximately 1.5 Petabytes (PB) of local solid state storage. In another example, solid state storage 41 may include up to 32 U.2×4 SSD devices. In other examples, NSCU 40 may support other SSD devices, e.g., 2.5″ Serial ATA (SATA) SSDs, mini-SATA (mSATA) SSDs, M.2 SSDs, and the like.

In the above described example in which each of the DPUs 17 is included on an individual DPU sled with local storage for the DPU, each of the DPU sleds may include four SSD devices and some additional storage that may be hard drive or solid state drive devices. In this example, the four SSD devices and the additional storage may provide approximately the same amount of storage per DPU as the six SSD devices described in the previous example.

In one example, each of DPUs 17 supports a total of 96 PCIe lanes. In this example, each of connections 48 may be an 8×4-lane PCI Gen 3.0 connection via which each of DPUs 17 may communicate with up to eight SSD devices within solid state storage 41. In addition, each of connections 50 between a given DPU 17 and the four storage nodes 12 and/or compute nodes 13 within the node group 52 supported by the DPU 17 may be a 4×16-lane PCIe Gen 3.0 connection. In this example, DPU group 19 has a total of 256 external facing PCIe links that interface with node groups 52. In some scenarios, DPUs 17 may support redundant server connectivity such that each of DPUs 17 connects to eight storage nodes 12 and/or compute nodes 13 within two different node groups 52 using an 8×8-lane PCIe Gen 3.0 connection.

In another example, each of DPUs 17 supports a total of 64 PCIe lanes. In this example, each of connections 48 may be an 8×4-lane PCI Gen 3.0 connection via which each of DPUs 17 may communicate with up to eight SSD devices within solid state storage 41. In addition, each of connections 50 between a given DPU 17 and the four storage nodes 12 and/or compute nodes 13 within the node group 52 supported by the DPU 17 may be a 4×8-lane PCIe Gen 4.0 connection. In this example, DPU group 19 has a total of 128 external facing PCIe links that interface with node groups 52.

In accordance with the techniques of the disclosure, an I/O expansion device is disclosed that is configured for slidable insertion within and removal from a plurality of slots (e.g., two) of a storage rack of data center 10. As described in further detail below, the I/O expansion device operates as a multi-slot front caddy that is designed to extend an I/O interface of the storage rack so as to allow interconnection between DPUs 17 and storage nodes 12 and/or compute nodes 13 external from the rack. With respect to the example of FIG. 3, a server rack may only provide sufficient interfaces and/or space for a DPU 17 to interface with, e.g., 4 storage nodes 12 and/or compute nodes 13 via PCIe link 50. The I/O expansion device disclosed herein serves to extend PCIe link 50 to enable DPU 17 to further interface with additional storage nodes 12 and/or compute nodes 13 external to the server rack. Moreover, as described herein, using the multi-slot I/O expansion device, the external storage nodes 12 and/or compute nodes 13 can be conveniently connected to PCIe link 50 via the front of the storage rack. In one example, the multi-slot caddy extends PCIe link 50 without requiring extra physical space or power but instead occupies the same space and utilizes the power otherwise allocated for front-loaded solid-state or hard disk drives typically inserted within the slots of the storage rack.

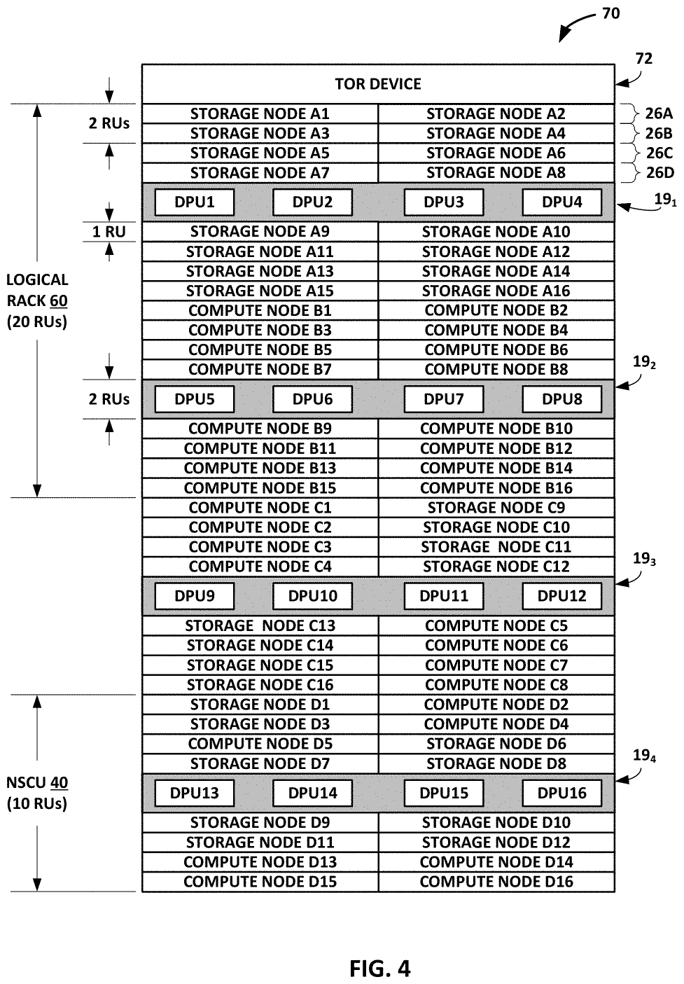

FIG. 4 is a block diagram illustrating an example arrangement of a full physical rack 70 including two logical racks 60. In the illustrated example of FIG. 4, rack 70 has 42 rack units or slots in vertical height including a 2 rack unit (2RU) top of rack (TOR) device 72 for providing connectivity to devices within switch fabric 14. In one example, TOR device 72 comprises a top of rack Ethernet switch. In other examples, TOR device 72 comprises an optical permutor described in further detail below. In some examples, rack 70 may not include an additional TOR device 72 and instead have the typical 40 rack units.

In the illustrated example, rack 70 includes four DPU groups 19₁-19₄ that are each separate network appliances 2RU in height. Each of the DPU groups 19 includes four DPUs and may be configured as shown in the example of FIG. 3. For example, DPU group 19₁ includes DPUs DPU1-DPU4, DPU group 192 includes DPUs DPU5-DPU8, DPU group 19₃ includes DPUs DPU9-DPU12, and DPU group 194 includes DPUs DPU13-DPU16. DPUs DPU1-DPU16 may be substantially similar to DPUs 17 described above.

Further, rack 70 includes a plurality of storage trays 26. Each storage tray 26 includes an electrical backplane configured to provide an interface between DPU 17 and one or more storage nodes 12 and compute nodes 13. Further, each storage tray 26 may provide power and physical support to one or more storage nodes 12 and compute nodes 13.

In this example, each of the DPU groups 19 supports sixteen storage nodes and/or compute nodes. For example, DPU group 19₁ supports storage nodes A1-A16, DPU group 192 supports compute nodes B1-B16, DPU group 19₃ supports compute nodes C1-C8 and storage nodes C9-C16, and DPU group 19₄ supports storage nodes D1, D3, D6-D12 and compute nodes D2, D4, D5, and D13-D16. Each storage node or compute node may be a dual-socket or dual-processor server sled that is ½ Rack in width and 1RU in height. In some examples, four of the storage nodes or compute nodes may be arranged into a node group 52 that is 2RU in height. For example, node group 52A includes storage nodes A1-A4, node group 52B includes storage nodes A5-A8, node group 52C includes storage nodes A9-A12, and storage group 52D includes storage nodes A13-A16. Nodes B1-B16, C1-C16, and D1-D16 may be similarly arranged into node groups 52.

DPU groups 19 and node groups 52 are arranged into NSCUs 40 from FIGS. 3-4. NSCUs 40 are 10RU in height and each include one 2RU DPU group 19 and four 2RU node groups 52. As illustrated in FIG. 4, DPU groups 19 and node groups 52 may be structured as a compute sandwich, in which each DPU group 19 is “sandwiched” between two node groups 52 on the top and two node groups 52 on the bottom. For example, with respect to DPU group 19₁, node group 52A may be referred to as a top second server, node group 52B may be referred to as a top server, node group 52C may be referred to as a bottom server, and node group 52D may be referred to as a bottom second server. In the illustrated structural arrangement, DPU groups 19 are separated by eight rack units to accommodate the bottom two 2RU node groups 52 supported by one DPU group and the top two 2RU node groups 52 supported by another DPU group.

NSCUs 40 may be arranged into logical racks 60, i.e., half physical racks. Logical racks 60 are 20RU in height and each include two NSCUs 40 having full mesh connectivity. In the illustrated example of FIG. 4, DPU group 19₁ and DPU group 19₂ are included in the same logical rack 60 along with their respective supported storage and compute nodes A1-A16 and B1-B16. In some examples, DPUs DPU1-DPU8 included the same logical rack 60 are connected to each other in an 8-way mesh. DPUs DPU9-DPU16 may be similarly connected in an 8-way mesh within another logical rack 60 includes DPUs groups 193 and 194 along with their respective storage and compute nodes C1-C16 and D1-D16.

Logical racks 60 within rack 70 may be connected to the switch fabric directly or through an intermediate top of rack device 72. As noted above, in one example, TOR device 72 comprises a top of rack Ethernet switch. In other examples, TOR device 72 comprises an optical permutor that transports optical signals between DPUs 17 and core switches 22 and that is configured such that optical communications are “permuted” based on wavelength so as to provide full-mesh connectivity between the upstream and downstream ports without any optical interference.

In the illustrated example, each of the DPU groups 19 may connect to TOR device 72 via one or more of the 8×100 GE links supported by the DPU group to reach the switch fabric. In one case, the two logical racks 60 within rack 70 may each connect to one or more ports of TOR device 72, and TOR device 72 may also receive signals from one or more logical racks within neighboring physical racks. In other examples, rack 70 may not itself include TOR device 72, but instead logical racks 60 may connect to one or more TOR devices included in one or more neighboring physical racks.

For a standard rack size of 40RU it may be desirable to stay within a typical power limit, such as a 15 kilowatt (kW) power limit. In the example of rack 70, not taking the additional 2RU TOR device 72 into consideration, it may be possible to readily stay within or near the 15 kW power limit even with the sixty-four storage nodes and compute nodes and the four DPU groups. For example, each of the DPU groups 19 may use approximately 1 kW of power resulting in approximately 4 kW of power for DPU groups. In addition, each of the storage nodes and compute nodes may use approximately 200 W of power resulting in around 12.8 kW of power for node groups 52. In this example, the 40RU arrangement of DPU groups 19 and node groups 52, therefore, uses around 16.8 kW of power.

In accordance with the techniques of the disclosure, an I/O expansion device is disclosed that is configured for slidable insertion within and removal from a plurality of slots (e.g., two) of a storage tray 26 of storage rack 70. As described in further detail below, the I/O expansion device operates as a multi-slot front caddy that is designed to extend an I/O interface of the storage tray 26 of storage rack 70 so as to allow interconnection between DPUs 17 and storage nodes 12 and/or compute nodes 13 external from the storage tray 26. With respect to the example of FIG. 4, a storage tray of server rack 70 may only provide sufficient interfaces and/or space for a DPU 17 to interface with, e.g., several storage nodes 12 and/or compute nodes 13. The I/O expansion device disclosed herein serves to extend an interface of a storage tray to additional storage nodes 12 and/or compute nodes 13 external to the storage tray. In some examples, the I/O expansion device disclosed herein serves to extend an interface of the storage tray to additional storage nodes 12 and/or compute nodes 13 located in a different storage tray of server rack 70. In some examples, the I/O expansion device disclosed herein serves to extend an interface of the storage tray to additional storage nodes 12 and/or compute nodes 13 located in a storage tray of a different server rack 70.

Moreover, as described herein, using the multi-slot I/O expansion device, the external storage nodes 12 and/or compute nodes 13 can be conveniently connected to one or more interfaces of the storage tray via the front of the storage tray 26. In one example, the multi-slot caddy extends the one or more interfaces of the storage tray without requiring extra physical space or power but instead occupies the same space and utilizes the power otherwise allocated for front-loaded solid-state or hard disk drives typically inserted within the slots of the storage rack.

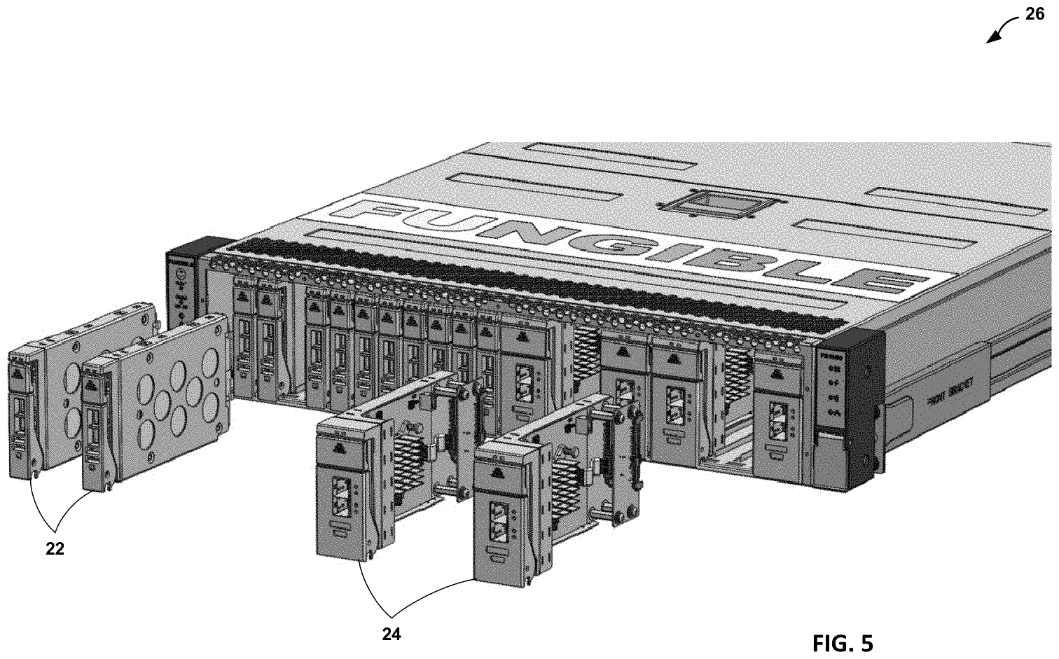

FIG. 5 is an illustration depicting an example storage tray 26 that includes a plurality of storage devices 22 and example I/O expansion devices 24 in accordance with the techniques of the disclosure. Storage tray 26 may be an example implementation of one of storage nodes 12₁-12₈ or compute nodes 13₁-13₈ of FIG. 3 or storage nodes A1-A16, C9-C16, D1, D3, and D6-D12 or compute nodes B1-B16, C1-C8 D2, D4, D5, and D13-D16 of FIG. 4.

In some examples, storage tray 26 includes a combination of one or more removable storage devices 22 and one or more I/O expansion devices 24. In further examples, storage tray 26 includes only storage devices 22. In still further examples, storage tray 26 includes only removeable expansion devices 24. Storage tray 26 provides a plurality of slots for mechanically seating and supporting storage devices 22 and removeable expansion devices 24.

Storage tray 26 further provides an electrical backplane comprising a plurality of interfaces for electrically interfacing with each of storage devices 22 and removeable expansion devices 24. In one example, the electrical backplane comprises a plurality of PCIe connectors that interface with each of storage devices 22 and removeable expansion devices 24 to connect storage devices 22 and removeable expansion devices 24 to one or more high-speed PCIe lanes.

Storage devices 22 may be one or more storage media for data storage. In some examples, each storage device 22 is a solid-state drive (SSD) storage device. In some examples, each storage device 22 is a 3.5″ drive that conforms to SFF-8300 and SFF-8301 as incorporated into the EIA-740 specification by the Electronic Industries Association (EIA). In some examples, storage device 22 comprises flash memory. Each of storage devices 22 comprises a rear plate including an electrical connector mounted thereon for interfacing with the backplane of storage tray 26. In some examples, the electrical connector comprises a single SFF-8639 (U.2) form factor connector. In some examples, the electrical connector interfaces with up to four PCIe lanes of the electrical backplane.

In accordance with the techniques of the disclosure, removeable expansion devices 24 are described. Removeable expansion devices 24 is configured to insert within a plurality of slots of storage tray 26. In other words, each of I/O expansion device 24 is a multi-slot device that occupies multiple slots of the storage tray 26. As shown, each of I/O expansion device 24 operates as a multi-slot front caddy that is designed to extend an I/O interface of the storage tray 26 so as to allow interconnection with storage and/or compute equipment external from the rack. Moreover, as described herein, using one or more of multi-slot I/O expansion device 24, external storage and/or compute nodes can be conveniently connected via the front of the storage tray 26. In one example, each multi-slot I/O expansion device 24 extends the I/O interface of storage rack 24 without requiring extra physical space or power but instead occupies the same space and utilizes power otherwise allocated to the slots for front-loaded solid-state or hard disk drives typically inserted within the storage rack.

In the example of FIG. 5, expansion device 24 includes a front plate comprising an aggregate electrical storage connector mounted thereon. The aggregate electrical storage connector is configured to interface with one or more storage devices and computing devices (not depicted). Expansion device 24 further comprises a rear plate comprising a plurality of backplane electrical connectors mounted thereon, wherein the plurality of backplane electrical connectors are configured to interface with the electrical backplane of storage tray 26. In some examples, expansion device 24 is the size of two side-by-side 3.5″ drives that conform to SFF-8300 and SFF-8301 as incorporated into the EIA-740 specification by the Electronic Industries Association (EIA). In some examples, the plurality of backplane electrical connectors comprise two SFF-8639 (U.2) form factor connectors configured to interface with up to eight PCIe lanes of the electrical backplane of storage tray 26. In accordance with the techniques of the disclosure, expansion device 26 is configured to present, via the plurality of backplane electrical connectors, an aggregate bandwidth of the plurality of high-speed PCIe lanes of the electrical backplane to storage and computing devices interfaced with the aggregate electrical storage connector.

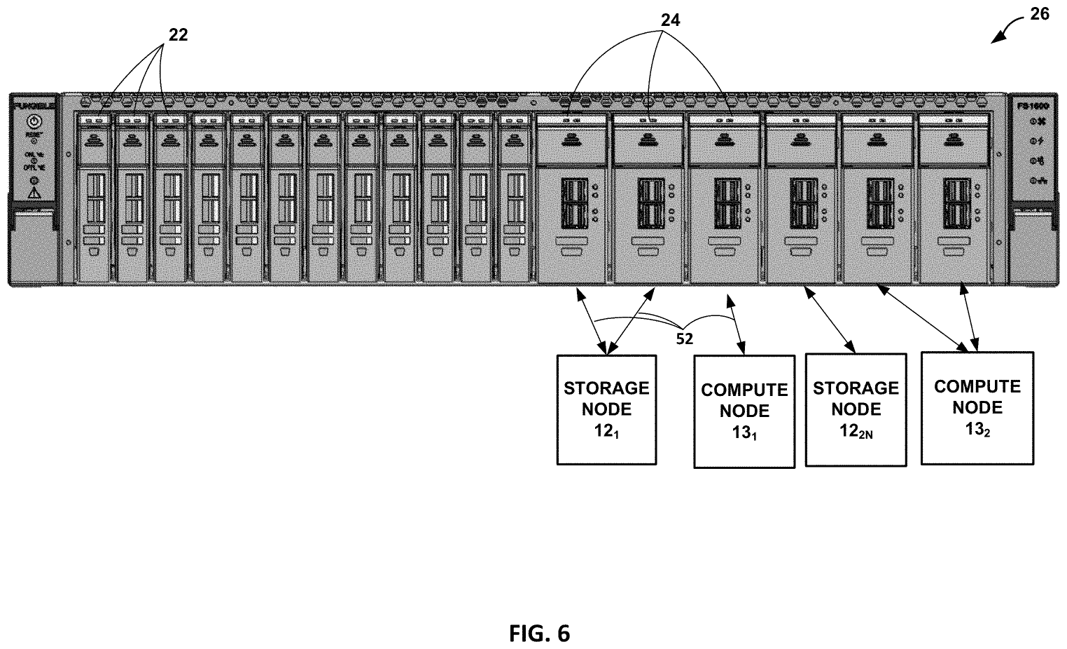

FIG. 6 is an illustration depicting another perspective of the example server rack of FIG. 5. In the example of FIG. 6, storage tray 26 includes 12 removable storage devices 22 and six I/O expansion devices 24 configured for slidable insertion within and removal from slots within storage tray 26.

In some examples, removeable expansion devices 24 provide an innovative system package that provides high level of fungibility, composability, and expandability for interconnecting with storage nodes 12₁-12₂ and compute nodes 13₁-13₂.

A generic piece of data center storage equipment, such as storage tray 26, typically has a plurality of storage bays accessible via a front plate of the storage tray 26. Each storage bay is configured for insertion of a storage device 22. Further, each storage bay includes an internal electrical backplane interface that is configured to interface with an interface mounted on a rear plate of storage device 22. Designers and customers may desire to maximize the storage capacity of a system while requiring easy accessibility, expandability, and fungibility.

In a typical implementation of tray 26, storage devices 22 communicate to a storage controller or other device, such as DPU 17, via an internal backplane of tray 26 using rear-facing connectors implementing Serial Attached Small Computer System Interface (SCSI) (SAS), Serial Advanced Technology Attachment (SATA), or PCIe. Storage devices 22 generally operate as endpoints on the serial interface so as to terminate the serial interface locally. Thus, the storage scale of an individual storage tray 26 is typically limited to the available slots in storage tray 26 for receiving storage drives of standard format. This limits the expandability, fungibility, and composability of storage tray 26. The restriction of being limited to devices insertable within the slots may force customers to buy additional equipment to install additional components, even though the full bandwidth and/or throughput of an additional storage tray 26 is not used to full capacity (because each storage tray 26 may not be available in suitable incremental sizes). Further, purchasing additional equipment adds to the equipment cost and operational cost of the data center. Today's products are typically constrained to fixed local spaces when supporting a plurality of types of storage and/or compute devices, and may provide additional limits on the flexibility of storage tray 26.

Accordingly, a removeable expansion device, such as removeable expansion devices 24, is described that eliminates this limitation and allows customers to have huge fungibility, composability, and expandability in terms of capacity and also in terms of the use of a plurality of simultaneously-supported interfaces in desired incremental steps or capacities.

In some examples, each expansion device 24 is a multi-slot (e.g., dual-slot) front caddy that is specially designed to extend the interface out of the box to interconnect other external storage nodes 12 and/or compute nodes 13. Moreover, as described, this may be implemented in a way that does not require extra space or power, for example, and using the same form factor requirements as that of front-loaded U.2 solid state drives (SSDs) and/or hard disk drives (HDDs). Such a expansion device 24 allows a customer to implement a mixture of high-performance local storage and medium-performance scaleable storage by extending the reach of an interface of storage tray 26 to external equipment. Such techniques make storage tray 26 highly customizable across different types scales of storage nodes 12 and/or compute nodes 13. As an example, in a 24-slot storage system such as serer tray 26 of FIGS. 5 and 6, extreme configurations like “all local flash storage” (e.g., storage devices 22), external, scale-out storage (via expansion devices 24 connected to storage nodes 12), or external, scale-out compute (via expansion devices 24 connected to compute nodes 13), simultaneously can be achieved in a single storage tray 26. In some examples, such a expansion device 24 provides an interface that may connect to an external cable to extend the interfaces of a backplane of storage tray 26 to any external equipment for scale-out storage or compute functions.

Expansion device 24 provides a solution for scale-out of storage and compute functions to customers of data center 10. For example, a customer may use expansion device 24 to connect a DPU 17 of a DPU group 19 of existing equipment to additional lower-cost equipment so as to increase storage density and to enable storage tiering. For example, a customer may have some high performance Non-Volatile Memory Express (NVMe) SSDs as caches within storage tray 26 and have expansion devices 24 provide simultaneous connectivity to external, low-cost, warm-storage HDDs or other low-cost flash solutions. Thus, expansion devices 24 enable the highly efficient deployment of Host Controller Interface (HCl) stacks or fungible and composable infrastructure.

In some examples, in a fungible or composable architecture, expansion device 24 provides hooks for detecting and identifying an external interface of an external device, such as storage nodes 12 or compute nodes 13, interfaced with expansion device 24. Expansion device 24 may configure a DPU 17 with the identified external interface. Further, Expansion device 24 may manage hot insertion and removal of external devices according to such external interfaces.

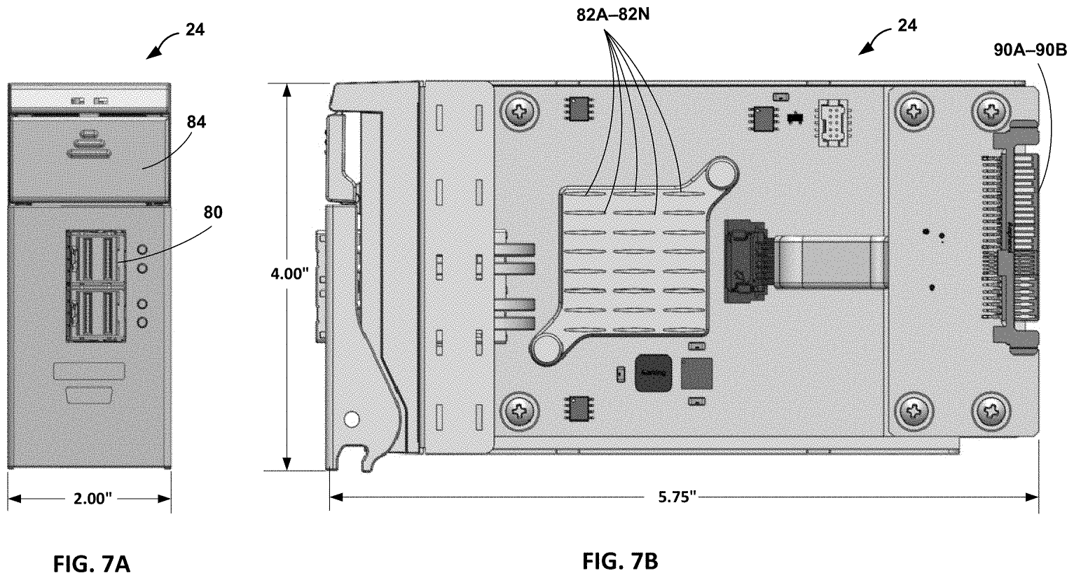

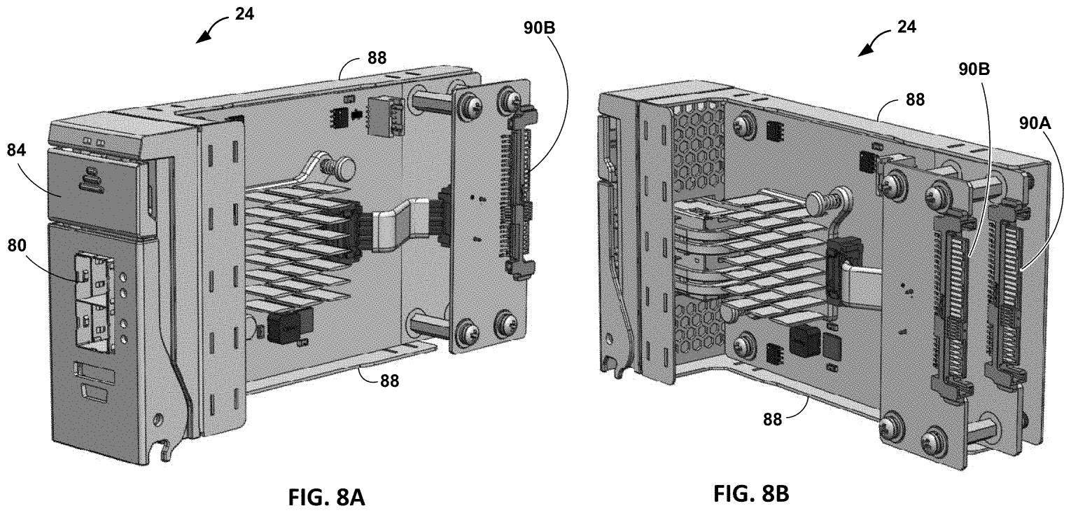

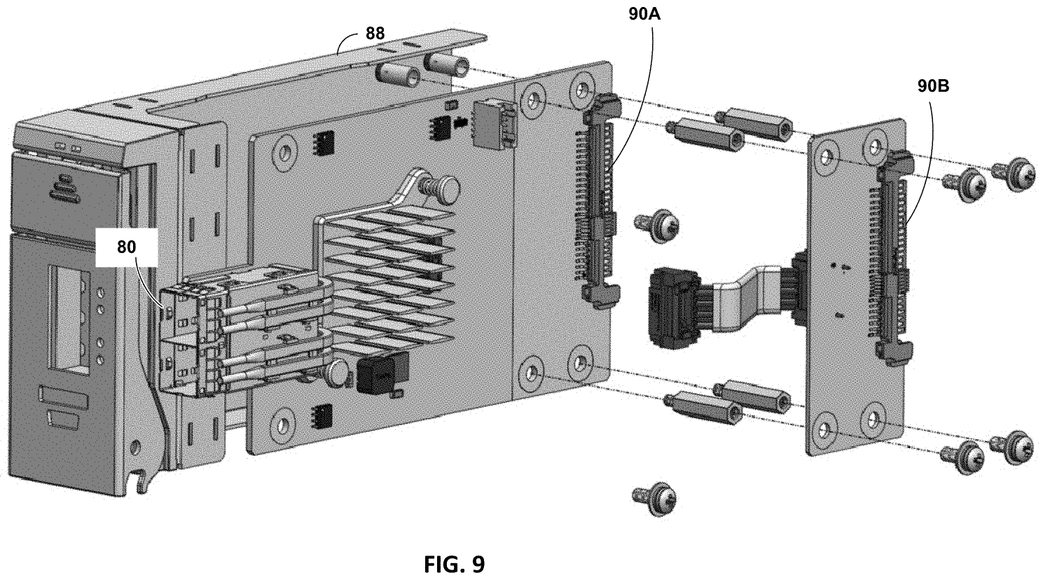

FIGS. 7A-7B are illustrations depicting a front view and a side view, respectively, of an example expansion device 24 in accordance with the techniques of the disclosure. FIGS. 8A-8B are illustrations depicting additional perspectives of the example expansion device 24 of FIGS. 7A-7B. FIG. 9 is an illustration depicting an exploded view of the example expansion device 24 of FIGS. 7A-7B.

I/O expansion devices 24 is configured for slidable insertion within and removal from a plurality of slots of storage tray 26. In some examples, expansion devices 24 includes one or more rails 88 configured to slideably engage storage tray 26 and position expansion devices 24 within one or more slots of storage tray 26.

Expansion device 24 includes front plate 84 comprising aggregate electrical storage connector 80 mounted thereon. Aggregate electrical storage connector 80 is configured to expose a front-facing electrical interface for connecting to one or more storage devices and computing devices, such as storage devices 12 and compute nodes 13 of FIG. 6. Expansion device 24 further comprises a rear plate comprising a plurality of backplane electrical connectors 90A-90B (collectively, “backplane electrical connectors 90”) mounted thereon, wherein backplane electrical connectors 90 are configured to interface with the electrical backplane of storage tray 26. In some examples, expansion device 24 is the size of two side-by-side 3.5″ drives that conform to SFF-8300 and SFF-8301 as incorporated into the EIA-740 specification by the Electronic Industries Association (EIA). In some examples, backplane electrical connectors 90 comprise two SFF-8639 (U.2) form factor connectors configured to interface with up to eight PCIe lanes of the electrical backplane of storage tray 26.

In accordance with the techniques of the disclosure, expansion device 26 is configured to present, via backplane electrical connectors 90, an aggregate bandwidth of the plurality of high-speed PCIe lanes of the electrical backplane to storage devices 12 and computing devices 13 interfaced with aggregate electrical storage connector 80. In some examples, backplane electrical connectors 90 comprise 2 PCIe x4 interfaces. In some examples, aggregate electrical storage connector 80 interfaces with compute devices 13 via the PCIe protocol. In some examples, aggregate electrical storage connector 80 comprises 8 PCIe x1 interfaces.

In some examples, expansion device 26 includes interface circuitry mounted on a printed circuit board within expansion device 26 and electrically coupled to backplane electrical connectors 90 of the rear plate and aggregate electrical storage connector 80 of the front plate. In some examples, backplane electrical connectors 90 are configured to interface with the plurality of high-speed PCIe lanes of the electrical backplane of storage tray 26 according to a PCIe protocol. Aggregate electrical storage connector interface with the one or more storage nodes 12 and computing nodes 13 according to the PCIe protocol. In this example, the interface circuitry comprises one or more of an electrical buffer and an electrical aggregator. The interface circuitry is configured to receive, from storage nodes 12 and computing nodes 13 and via aggregate electrical storage connector 80, first data according to the PCIe protocol and output, to the plurality of high-speed PCIe lanes of the electrical backplane of storage tray 26 and via plurality of backplane electrical connectors 90, the first data according to the PCIe protocol. Further, the interface circuitry is configured to receive, from the plurality of high-speed PCIe lanes of the electrical backplane of server 26 and via plurality of backplane electrical connectors 90, second data according to the PCIe protocol and output, to storage nodes 12 and computing nodes 13 and via aggregate electrical storage connector 80, second data according to the PCIe protocol.

In some examples, aggregate electrical storage connector 80 interfaces with storage devices 12 via an interface storage protocol that is different from the PCIe protocol. In such an example, the interface circuitry of expansion device 24 includes interface conversion circuitry configured to receive data from the electrical backplane of server 26 via the PCIe protocol and output data to external devices according to the interface storage protocol. Further, the interface conversion circuitry is configured to receive data from the external devices according to the interface storage protocol and output data to the electrical backplane of serer 26 via the PCIe protocol.

In one example, expansion device 26 is configured to receive, from one or more storage devices 12 and computing devices 13 and via aggregate electrical storage connector 80, first data according to the interface storage protocol that is different from the PCIe protocol and output, to the plurality of high-speed PCIe lanes of the electrical backplane and via backplane electrical connectors 90, the first data according to the PCIe protocol. Further, expansion device 26 is configured to receive, from the plurality of high-speed PCIe lanes of the electrical backplane and via backplane electrical connectors 90, second data according to the PCIe protocol and output, to one or more storage devices 12 and computing devices 13 and via aggregate electrical storage connector 80, the second data according to the interface storage protocol that is different from the PCIe protocol.

For example, aggregate electrical storage connector 80 interfaces with storage devices 12 via SAS protocol, and aggregate electrical storage connector 80 comprises a plurality of SAS connectors. In some examples, aggregate electrical storage connector 80 comprises 8 SAS connectors. In another example, aggregate electrical storage connector 80 interfaces with storage devices 12 via SATA protocol, and aggregate electrical storage connector 80 comprises a plurality of SATA connectors. In some examples, aggregate electrical storage connector 80 comprises 8 SATA connectors.

The techniques described in this disclosure may be implemented, at least in part, in hardware, software, firmware or any combination thereof. For example, various aspects of the described techniques may be implemented within one or more processors, including one or more microprocessors, digital signal processors (DSPs), application specific integrated circuits (ASICs), field programmable gate arrays (FPGAs), or any other equivalent integrated or discrete logic circuitry, as well as any combinations of such components. The term “processor” or “processing circuitry” may generally refer to any of the foregoing logic circuitry, alone or in combination with other logic circuitry, or any other equivalent circuitry. A control unit comprising hardware may also perform one or more of the techniques of this disclosure.

Such hardware, software, and firmware may be implemented within the same device or within separate devices to support the various operations and functions described in this disclosure. In addition, any of the described units, modules or components may be implemented together or separately as discrete but interoperable logic devices. Depiction of different features as modules or units is intended to highlight different functional aspects and does not necessarily imply that such modules or units must be realized by separate hardware or software components. Rather, functionality associated with one or more modules or units may be performed by separate hardware or software components, or integrated within common or separate hardware or software components.

The techniques described in this disclosure may also be embodied or encoded in a computer-readable medium, such as a computer-readable storage medium, containing instructions. Instructions embedded or encoded in a computer-readable storage medium may cause a programmable processor, or other processor, to perform the method, e.g., when the instructions are executed. Computer readable storage media may include random access memory (RAM), read only memory (ROM), programmable read only memory (PROM), erasable programmable read only memory (EPROM), electronically erasable programmable read only memory (EEPROM), flash memory, a hard disk, a CD-ROM, a floppy disk, a cassette, magnetic media, optical media, or other computer readable media.

Various examples have been described. These and other examples are within the scope of the following claims.

What is claimed is:

1. A removable Input/Output (I/O) expansion device configured for slidable insertion within and removal from a plurality of slots of a storage rack having an electrical backplane comprising a plurality of high-speed Peripheral Component Interconnect Express (PCIe) lanes, the I/O expansion device comprising:
a front plate comprising an aggregate electrical storage connector mounted thereon, the aggregate electrical storage connector configured to interface with one or more storage devices and computing devices;
a rear plate comprising a plurality of backplane electrical connectors mounted thereon, wherein the plurality of backplane electrical connectors are configured to interface with the plurality of high-speed PCIe lanes of the electrical backplane of the storage rack;
interface circuitry mounted on a printed circuit board within the I/O expansion device and electrically coupled to the backplane electrical connectors of the rear plate and the aggregate electrical storage connector of the front plate,
wherein the interface circuitry of the I/O expansion device is configured to present, via the plurality of backplane electrical connectors, an aggregate bandwidth of the plurality of high-speed PCIe lanes to the one or more storage devices and computing devices interfaced with the aggregate electrical storage connector.

2. The I/O expansion device of claim 1,
wherein the plurality of backplane electrical connectors are configured to interface with the plurality of high-speed PCIe lanes of the electrical backplane according to a PCIe protocol,
wherein the aggregate electrical storage connector is further configured to interface with the one or more storage devices and computing devices according to the PCIe protocol, and
wherein the interface circuitry comprises one or more of an electrical buffer and an electrical aggregator configured to:
receive, from the one or more storage devices and computing devices and via the aggregate electrical storage connector, first data according to the PCIe protocol and output, to the plurality of high-speed PCIe lanes of the electrical backplane and via the plurality of backplane electrical connectors, the first data according to the PCIe protocol; and
receive, from the plurality of high-speed PCIe lanes of the electrical backplane and via the plurality of backplane electrical connectors, second data according to the PCIe protocol and output, to the one or more storage devices and computing devices and via the aggregate electrical storage connector, second data according to the PCIe protocol.

3. The I/O expansion device of claim 1,
wherein the plurality of backplane electrical connectors are configured to interface with the plurality of high-speed PCIe lanes of the electrical backplane according to a PCIe protocol,
wherein the aggregate electrical storage connector is further configured to interface with the one or more storage devices and computing devices according to an interface storage protocol that is different from the PCIe protocol, and
wherein the interface circuitry comprises interface conversion circuitry configured to:
receive, from the one or more storage devices and computing devices and via the aggregate electrical storage connector, first data according to the interface storage protocol that is different from the PCIe protocol and output, to the plurality of high-speed PCIe lanes of the electrical backplane and via the plurality of backplane electrical connectors, the first data according to the PCIe protocol; and
receive, from the plurality of high-speed PCIe lanes of the electrical backplane and via the plurality of backplane electrical connectors, second data according to the PCIe protocol and output, to the one or more storage devices and computing devices and via the aggregate electrical storage connector, the second data according to the interface storage protocol that is different from the PCIe protocol.

4. The I/O expansion device of claim 3,
wherein the interface storage protocol that is different from the PCIe protocol comprises a Serial Attached Small Computer System Interface (SCSI) (SAS) protocol, and
wherein the aggregate electrical storage connector comprises a plurality of SAS connectors.

5. The I/O expansion device of claim 4, wherein the plurality of SAS connectors comprise 8 SAS connectors.

6. The I/O expansion device of claim 3,
wherein the interface storage protocol that is different from the PCIe protocol comprises a Serial Advanced Technology Attachment (SATA) protocol, and
wherein the aggregate electrical storage connector comprises a plurality of SATA connectors.

7. The I/O expansion device of claim 6, wherein the plurality of SATA connectors comprise 8 SATA connectors.

8. The I/O expansion device of claim 1, wherein the aggregate electrical storage connector comprises 8 PCIe x1 interfaces.

9. The I/O expansion device of claim 1, wherein the plurality of backplane electrical connectors comprise 2 PCIe x4 interfaces.

10. The I/O expansion device of claim 1, further comprising one or more rails configured to slideably engage the storage rack and position the I/O expansion device within a slot of the plurality of slots of the storage rack.

11. The I/O expansion device of claim 1, wherein the plurality of backplane electrical connectors comprise two SFF-8639 (U.2) form factor connectors.

12. A method of forming a removable Input/Output (I/O) expansion device configured for slidable insertion within and removal from a plurality of slots of a storage rack having an electrical backplane comprising a plurality of high-speed Peripheral Component Interconnect Express (PCIe) lanes comprising:
forming a front plate comprising an aggregate electrical storage connector mounted thereon, the aggregate electrical storage connector configured to interface with one or more storage devices and computing devices;
forming a rear plate comprising a plurality of backplane electrical connectors mounted thereon, wherein the plurality of backplane electrical connectors are configured to interface with the plurality of high-speed PCIe lanes of the electrical backplane of the storage rack, and
forming interface circuitry mounted on a printed circuit board within the I/O expansion device and electrically coupled to the backplane electrical connectors of the rear plate and the aggregate electrical storage connector of the front plate,
wherein the interface circuitry of the I/O expansion device is configured to present, via the plurality of backplane electrical connectors, an aggregate bandwidth of the plurality of high-speed PCIe lanes to the one or more storage devices and computing devices interfaced with the aggregate electrical storage connector.

13. The method of claim 12,
wherein the plurality of backplane electrical connectors are configured to interface with the plurality of high-speed PCIe lanes of the electrical backplane according to a PCIe protocol,
wherein the aggregate electrical storage connector is further configured to interface with the one or more storage devices and computing devices according to the PCIe protocol, and
wherein the interface circuitry comprises one or more of an electrical buffer and an electrical aggregator,
the method further comprising:
receiving, from the one or more storage devices and computing devices and via the aggregate electrical storage connector, first data according to the PCIe protocol and output, to the plurality of high-speed PCIe lanes of the electrical backplane and via the plurality of backplane electrical connectors, the first data according to the PCIe protocol; and
receiving, from the plurality of high-speed PCIe lanes of the electrical backplane and via the plurality of backplane electrical connectors, second data according to the PCIe protocol and output, to the one or more storage devices and computing devices and via the aggregate electrical storage connector, second data according to the PCIe protocol.

14. The method of claim 12,
wherein the plurality of backplane electrical connectors are configured to interface with the plurality of high-speed PCIe lanes of the electrical backplane according to a PCIe protocol,
wherein the aggregate electrical storage connector is further configured to interface with the one or more storage devices and computing devices according to an interface storage protocol that is different from the PCIe protocol, and
wherein the interface circuitry comprises interface conversion circuitry,
the method further comprising:
receiving, from the one or more storage devices and computing devices and via the aggregate electrical storage connector, first data according to the interface storage protocol that is different from the PCIe protocol and output, to the plurality of high-speed PCIe lanes of the electrical backplane and via the plurality of backplane electrical connectors, the first data according to the PCIe protocol; and
receiving, from the plurality of high-speed PCIe lanes of the electrical backplane and via the plurality of backplane electrical connectors, second data according to the PCIe protocol and output, to the one or more storage devices and computing devices and via the aggregate electrical storage connector, the second data according to the interface storage protocol that is different from the PCIe protocol.

15. The method of claim 14,
wherein the interface storage protocol that is different from the PCIe protocol comprises a Serial Attached Small Computer System Interface (SCSI) (SAS) protocol, and
wherein the aggregate electrical storage connector comprises a plurality of SAS connectors.

16. The method of claim 14,
wherein the interface storage protocol that is different from the PCIe protocol comprises a Serial Advanced Technology Attachment (SATA) protocol, and
wherein the aggregate electrical storage connector comprises a plurality of SATA connectors.

17. The method of claim 12,
wherein the aggregate electrical storage connector comprises 8 PCIe x1 interfaces, and
wherein the plurality of backplane electrical connectors comprise 2 PCIe x4 interfaces.

18. The method of claim 12, further comprising forming one or more rails configured to slideably engage the storage rack and position the I/O expansion device within a slot of the plurality of slots of the storage rack.

19. The method of claim 12, wherein the plurality of backplane electrical connectors comprise two SFF-8639 (U.2) form factor connectors.

20. A removable Input/Output (I/O) expansion device configured for slidable insertion within and removal from a plurality of slots of a storage rack having an electrical backplane comprising a plurality of high-speed Peripheral Component Interconnect Express (PCIe) lanes, the I/O expansion device comprising:
a front plate comprising means for interfacing with one or more storage devices and computing devices;
a rear plate comprising a plurality of means for interfacing with the plurality of high-speed PCIe lanes of the electrical backplane of the storage rack;
interface means electrically coupled to the means for interfacing with one or more storage devices and computing devices and the plurality of means for interfacing with the plurality of high-speed PCIe lanes of the electrical backplane,
wherein the interface means is configured to present, via the plurality of means for interfacing with the plurality of high-speed PCIe lanes of the electrical backplane, an aggregate bandwidth of the plurality of high-speed PCIe lanes to the one or more storage devices and computing devices interfaced with the means for interfacing with one or more storage devices and computing devices.
